(19) United States
(12) Patent Application Publication
(10) Pub. No.: US 2004/0071234 A1
(43) Pub. Date: Apr. 15, 2004

(54) High rate receiver

(75) Inventor: Wenzhen Li, Singapore (SG)

Correspondence Address: OSTROLENK FABER GERB & SOFFEN, 1180 AVENUE OF THE AMERICAS, NEW YORK, NY, 100368403

(73) Assignee: Oki Techno Centre (Singapore) Pte Ltd

(21) Appl. No.: 10/623,000

(22) Filed: Jul. 18, 2003

(30) Foreign Application Priority Data
Jul. 18, 2002 (SG) SG 200204400-6

(51) Int. Cl. H03D 1/00; H04L 27/06

(52) U.S. Cl. 375/341

(57) ABSTRACT

The present invention relates to wireless burst communications receivers especially for high-rate indoor applications. The present invention provides a phase lock loop (PLL) circuit for receiving a burst signal including a repeated preamble sequence and a data sequence, the circuit comprising a maximum likelihood sequence estimator (MLSE) and means for determining the phase difference between a signal at the output of the MLSE and a corresponding delayed signal at the input of the MLSE, phase rotating means for rotating the phase of said burst signal dependent on said phase difference, the output of said means being coupled to the MLSE input, wherein the phase determining means is further arranged to determine the phase difference between a non-delayed signal at the MLSE input and a stored preamble sequence signal.

### FIELD OF THE INVENTION

The present invention relates to wireless burst communications receivers especially for high-rate indoor applications. The invention particularly relates to MLSE based joint carrier, channel, timing and data estimation receivers.

### BACKGROUND OF THE INVENTION

In time-division burst communication systems intersymbol interference (ISI) and noise, along with errors in the carrier phase and the sample timing, are the primary impediments to reliable data reception. Realising reliable high-rate burst communications involves the following key techniques: efficient equalisation to combat the severe ISI caused by frequency-selective fading channel; carrier recovery to compensate for the frequency offset and phase noise; timing recovery to compensate for timing offset and channel estimation for efficient equalisation.

It will be appreciated by those skilled in the art that the equalisers can be classified as linear equaliser, decision feed back equalisers (DFE), and maximum-likelihood sequence estimation (MLSE) equaliser. Among them MLSE utilising Viterbi algorithm is considered an optimal equaliser.

There is a huge amount of work on joint carrier, channel and data estimation for TDMA systems. Early in 1974, Ungerboeck proposed a adaptive receiver structure in Gottfried Ungerboeck “Adaptive maximum likelihood receiver for carrier modulated data transmission systems”, IEEE Trans. on Comm., Vol. com-22, No.5, May 1974 pp 624-636. This jointly estimates carrier, timing, channel and data. Based on the Ungerboeck's concept, R.D.'avella et al proposed a receiver structure in Renato D'Avella, Luigi Moreno, and Marcello Sant'Agostino, “An adaptive MLSE receiver for TDMA digital mobile radio”, IEEE Journal on Selected Area in Communications, Vol.7, No.1, January 1989 pp 122-129. In this RENATO's system, a new CIR (channel impulse response) estimate is obtained from each received burst, which is used to drive the coefficients of the matched filter (MF). The channel variations during the transmission can be compensated by the adaptation loops by adjusting the MF coefficients, the Viterbi processor parameters and the signal phase. During the adaptation, gradient algorithms are used to minimise the mean square error as suggest by Ungerboeck. We can see that two independent adaptation functions: the CIR variation tracking and phase variation tracking are adopted. The CIR tracking is implemented by adjusting the MF coefficients and the Viterbi processor parameters, and the phase adaptation is performed immediately before the Viterbi processor in order to minimise the overall loop delay.

Although the above CIR tracking could noticeably improve the system performance where the preamble sequence is at the beginning of the burst, it seems to be less useful in GSM systems where the preamble is in the middle of the burst. Moreover, this adaptation procedures obviously increase the processing load. To solve this problem, Ling, et al., “Method and apparatus for providing carrier frequency offset compensation in a TDMA communication system”, U.S. Pat. No. 5,245,611, Sep. 14, 1993 proposed a improved receiver structure for TDMA systems to compensate for carrier frequency offset and the caused CIR variation. The CIR estimate is assumed to be constant for the whole burst. The modified Ling receiver structure includes: the phase is corrected before matched filter (a big loop adaptation compared to the RENATO's small loop adaptation); the adaptation of the MF coefficients and VA parameters are not adopted; several frequency offset estimation methods are proposed. This modified structure possess much lower complexity and acceptable performance.

However, these above MLSE receivers can only compensate for small frequency offset which cause distortion of the channel on burst-by-burst basis. This is because MLSE may introduce a quite long decision delay, which is prohibitive to the applications of decision-directed phase-lock-loop (PLL) to track the large frequency offset. To increase the frequency tracking range, MLSE with tentative decision combined with PLL is also adopted in Serizawa, et al., “Carrier phase synchronous type maximum likelihood decoder”, U.S. Pat. No. 5,311,523, May 10, 1994. This does not contain a long delay, and shows good tracking performance when SNR is high. However, in such a phase lock loop, when the tentative decision is not correct, the problem of error propagation result, this is especially so in the low SNR condition. To solve the problem of error propagation of tentative decision, per-survivor processing (PSP) technique are extensively studied in art for joint carrier, channel and data estimation, e.g. in Serizawa above and Khalid A. Hamied, and Gordon L. Stuber, “An adaptive truncated MLSE receiver for Japanese personal digital cellular”, IEEE Transaction on Vehicular Technology, Vol.45, No.1, February, 1996 pp 41-50.

The intuitive rational for PSP technique used in MLSE is straightforward: whenever the incomplete knowledge of some quantities prevents us from calculating a particular transition metric in a precise and predictable from, we use estimates of those quantities based on the data sequence associated with the survivor leading to that transition. If any particular survivor is correct (an event of high probability under normal operating conditions), the corresponding estimates are evaluated using the correct data sequence. Since at each stage we do not know which survivor is correct (or the best), we extended using the best data sequence available (which is the sequence associated to it), regardless of our temporary ignorance as to which survivor is the best. When per-survivor processing (PSP) technique is used combined with MLSE, no decision delay is introduced into the PLL as same as in tentative decision methods, at the same time, the error propagation is avoided.

It is worthwhile noting that in the Ungerboeck's MLSE receiver, RENATO's receiver, and Ling's invention, besides a quite long decision delay caused by the Viterbi processor, extra delay is introduced into the PLL in RENATO's receiver and Ling's invention, which further narrow the frequency tracking range of the PLL. In these receivers, the detected phase error in the PLL is computed by comparing the signal sample at the Viterbi processor input with a replica of the same signal sample based on the decision output and the CIR. Therefore, the extra delay caused by signal reconstruction is introduced into the PLL, which limits the allowable carrier frequency offset ranges that can be compensated. Therefore, RENATO and Ungerboeck's MLSE receivers only consider small carrier frequency offset, which causes distortions within each received signal on a burst-by-burst basis.

In the Ling's improved MLSE receiver, although several frequency offset method are proposed to improve the accuracy and stability of the system, the PLL delay further increases as it adopted a big-loop architecture (the phase retotation was performed prior to the matched filter). The circuit for adjusting the regenerated carrier by utilising the phase error calculated on the basis of the detected data has a remarkably large delay time in the control loop, therefore, it is impossible to attain a good characteristics in the frequency and phase tracking. Namely, the circuit has disadvantages that a frequency tracking range becomes remarkably narrow, a time required for the synchronisation is remarkably long.

Although the MLSE receiver adopting tentative decision and combined with the PLL has a quite large tracking range, its BER performance is not so satisfied especially in the low SNR due to error propagation. Whereas PSP-based MLSE receivers, which can obtain a small delay as same as the MLSE receiver tentative decision, have much larger tracking range and much better BER performance at the low SNR. However, PSP MLSE receivers are characterised by a very high complexity in the implementation. First, if the state number of the Viterbi processor is also doubled, i.e., besides the survivor metrics for N states, the phase for N states are required to be stored in the each step of Viterbi processing. In addition, from the viewpoint of the PLL tracking performance, PSP technique which adopts LMS algorithm to track the carrier phase, is equivalent to a first-order PLL. As we know the extensively adopted second-order PLL has much better tracking performance than the first-order PLL.

Therefore, in a high-rate indoor wireless communication system where there may be a large frequency offset caused by either a Doppler frequency shift or a frequency difference between a transmitter and receiver's local oscillator, it would be extremely advantageous to provide an alternative MLSE receiver structure capable of providing large carrier frequency offset compensation and accurate joint channel/data estimation, while overcoming the shortcomings of the prior art.

### SUMMARY OF THE INVENTION

In general terms the present invention provides a wireless burst communications receiver especially for high rate indoor applications which utilises a fine frequency/phase estimation and tracking process which is advantageously combined with a large range coarse frequency/phase offset process. The fine frequency tracking function or apparatus uses a maximum-likelihood sequence estimation (MLSE) equaliser in combination with a dual mode phase lock loop (PLL). The PLL comprises a phase detector with a switchable input, one input option from the output of the MLSE or a memory component containing a copy of the expected preamble sequence. The second input option between a delayed and a non-delayed input of the MLSE. Initially the phase detector input is switched to the known preamble and non-delayed MLSE input to allow the phase lock loop to initialise and effectively adjust the phase of the incoming signal to correspond with the known preamble. One input is then switched from memory to the output of the MLSE following the processing delay required for it to process the first signal samples. The other input is switched to a delayed MLSE input, the delay corresponding to the processing delay of the MLSE. The PLL can then correct for changes in carrier frequency/phase during the burst.

In particular, the present invention provides a phase lock loop (PLL) circuit for receiving a burst signal including a repeated preamble sequence and a data sequence, the circuit comprising a maximum likelihood sequence estimator (MLSE) and means for determining the phase difference between a signal at the output of the MLSE and a corresponding delayed signal at the input of the MLSE, and phase rotating means for rotating the phase of said burst signal dependent on said phase difference, the output of said means being coupled to the MLSE input, wherein the phase determining means is further arranged to determine the phase difference between a non-delayed signal at the MLSE input and a stored preamble sequence signal.

This arrangement has several advantages including reducing the PLL acquisition time. By combining this with a large range coarse frequency of said estimation and correction function, there is provided a wide range frequency offset estimation and correction function with low implementation complexity and cost compared with other MLSE type receiver structures.

In particular, the invention provides a receiver having the above PLL together with means for differentially multiplying a sample of a first said preamble sequence with a corresponding sample of a second said preamble sequence, means for determining a phase rotation angle dependent on said difference and which angle is indicative of said estimate, a PLL having a mixer which receives a signal, an MLSE having an input coupled to the mixer, and a phase detector, the phase detector arranged to determine the phase difference between a signal at an output of the MLSE and a corresponding delayed signal at the MLSE input, the PLL further having mixer input means which is arranged to provide a rotating signal to the mixer in order to adjust the frequency of the received signal which the mixer outputs to the MLSE, said rotating signal being dependent on said phase difference, wherein the phase detector is arranged to be switchable between said MLSE output and a training sequence memory, and between said MLSE delayed input and a non-delayed MLSE input.

The invention also provides a phase error detector which further reduces PLL loop delay and improves phase tracking performance.

In particular the present invention provides a phase detector having an input coupled to the output of a maximum likelihood sequence estimator (MLSE) and a second input coupled to the input of said MLSE, the detector comprising delay means for delaying the second input signal by a delay time corresponding to the processing delay of the MLSE, and processing means arranged to determine the phase difference between the first and delayed second inputs, the processing means arranged to determine the imaginary part of the result of dividing the second input by the first input, said part corresponding to the phase difference.

Embodiments of the invention present a MLSE type receiver structure that integrates various estimation methods in an optimum way and adaptive manner for high-rate indoor wireless communications. Skillfully utilising the preamble sequence (CAZAC sequence) in the beginning of the burst, a simple and high accuracy frequency offset estimator is adopted. Then a small-loop structure based on the integration of MLSE and PLL is proposed. It is proven that the receiver structure can be optimised if Ungerboeck's MLSE is utilised and combined with the proposed dual mode PLL.

The residual frequency error and phase error are removed by applying a mixed data-aided and decision-directed PLL, and a new phase error detector method is proposed which introduces much smaller phase lock loop delay to improve the tracking performance of the PLL. This dual-mode PLL removes the residual frequency error and phase noise in two steps. First, the data-aided PLL is adopted by utilising the preamble sequence, which has zero decision delay. This step completes the initialisation of the PLL and help the PLL enter into the lock-state from the pull-in state. Then the PLL is switched to the decision-directed mode, the decision value from the output of the MLSE is feedback to the phase detector, the detected phase error passes through a second-order loop filter and drives the NCO. The output of NCO is used to correct the phase of the received signal. In the decision-directed model, the loop delay is mainly determined by the decision delay inherent in the MLSE.

An advantage of embodiments of the present invention is that such a receiver structure trades off accurate compensation for wide range frequency offset and low implementation complexity, as compared to other MLSE type receiver structures. This is achieved by using the property of the preamble CAZAC sequence for coarse frequency offset estimation and initiation of the PLL.

Unlike many prior art MLSE receivers, embodiments of the invention do not use PSP which requires lots of hardware, and instead overcomes the problem of potentially large offset by bypassing decision delay by switching PLL to known preamble initially to get coarse frequency and hence avoid problem of large frequency offset and slow response in typical PSP architectures.

By utilising Ungerboeck's unwhitened MLSE we can decrease the complexity of the Viterbi processor and improve the BER performance of the system. Moreover, we can optimise the receiver structure by combining this with the proposed dual-mode PLL.

The proposed new phase error detector used in the PLL further decreases the PLL loop delay and improves the phase tracking performance.

The above receiver structure improvements are advantageously combined with the following coarse frequency offset estimation and correction functions.

The present invention also provides an estimator for determining an estimate of frequency offset associated with a received burst signal having a repeated training sequence; the estimator comprising means for differentially multiplying a sample of a first said sequence with a corresponding sample of a second said sequence and means for determining a phase rotation angle dependent on said difference and which angle is indicative of said estimate.

Preferably the samples of each said training sequence are statistically independent, and wherein the estimator further comprises means for averaging said differences for a number of samples of said first and second sequences.

Preferably said sequences are Pseudo Random or Constant Amplitude Zero Auto-Correlation sequences.

Preferably said phase angle determining means comprises an arc tangent function applied to said difference.

There is also provided a frequency corrector comprising means for differentially multiplying a sample of a first said sequence with a corresponding sample of a second said sequence; means for determining a phase rotation angle dependent on said difference and which angle is indicative of said estimate and a frequency shifter which shifts the phase of said received signal by said phase rotation angle.

Preferably the phase shifter comprises an NCO having an input coupled to said phase rotation output and which generates a correction frequency dependent upon said output and which is mixed with said received signals.

The repeated symbols within a sequence can be treated as statistically independent when using certain well-known sequences (e.g. PN or CAZAC) which allows for an improved frequency offset estimate. As is well-known, Pseudo Random (PN) and Constant Amplitude Zero Auto-Correlation (CAZAL) sequences provide that samples within a sequence are statistically independent. This is because each sequence in the preamble is normally chosen or designed to possess noise-like or pseudo-random properties. With repeated sequences, this statistically independent property (within each sequence of the entire preamble) allows the effect of a multipath (frequency-selective) communication channel on the quality of a frequency estimate to be substantially reduced by the combined process of differential multiplication and averaging. The averaging process removes the products which have statistically independent symbols while retaining only those which has identical symbols corresponding to the repeated sequences.

As the estimator exploits the use of preambles with periodic sequences or symbols, the estimation performance of this technique is particularly robust against frequency selective channel. Due to the feedforward nature of the frequency corrector, the implementation is highly suited for burst mode modem design. In a burst mode transmission system, the frequency offset is assumed to be invariant throughout each received packet. The frequency offset of many individually received packets can however be different. Therefore a single frequency estimate determined from the preamble of each packet can be used to cancel the frequency offset of that packet. Compared to feedback architecture, a feedforward estimator allows frequency offset to be estimated very reliably in a single-shot fashion. The estimator is then shut off during the remaining packet since it is not required to track any residual frequency offset since it is assumed to be invariant.

Whilst these various aspects of the invention are advantageously combined, they can also be implemented independently in receiver structures.

### BRIEF DESCRIPTION OF THE DRAWINGS

FIG. 1 is the diagram block of the considered transmitter's baseband structure.

FIG. 2 is the data structure of a WPAN system.

FIG. 3 is the diagram block of the considered receiver's baseband structure.

FIG. 4 is the block of coarse frequency offset estimator.

FIG. 5 is the integration method of MLSE and two-mode PPL.

FIG. 6 shows BER v SNR for prior art and inventive MLSE

FIG. 7 shows BER v SNR for prior art and inventive receiver architectures.

Table 1: CAZAC sequence

### DETAILED DESCRIPTION OF THE PREFERRED EMBODIMENTS

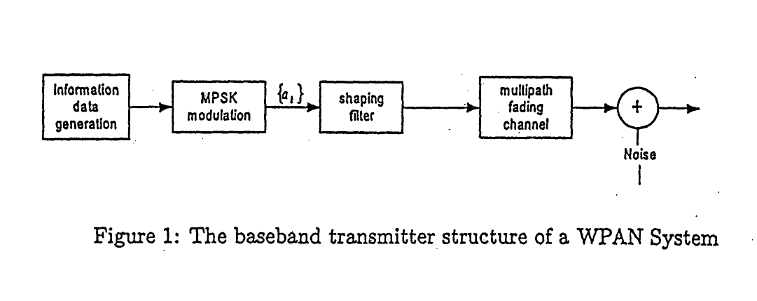

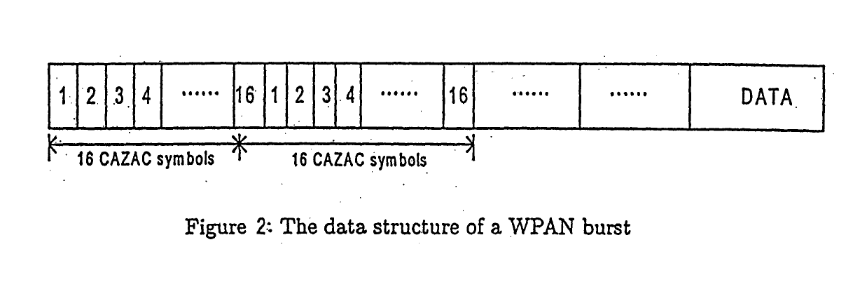

The baseband function blocks of a transmitter are schematically depicted in FIG. 1. The core of the baseband transmitter is the differential PSK mapping and the complex filter shaping. The channel model is also included in this figure. The high data rate WPAN and WLAN systems in indoor environment are low-mobility systems. Therefore, generally the channel can be considered as a frequency-selective and time-invarying fading channel for each burst transmission. This means that once the CIR (channel impulse response) is estimated, it is suitable for the whole packet. The data structure of a WPAN system (see IEEE802.15.3) are shown in FIG. 2. A physical layer preamble is added before the message payload to aid receiver algorithms related to synchronisation, carrier-offset recovery, and signal equalisation. The preamble consists of multiple periods of a special sequence of 16 symbols called a CAZAC sequence, which demonstrates a constant amplitude zero auto-correlation property. The CAZAC sequence shall be denoted as {c₀, c₁ . . . , c₁₅}. Each element, cᵢ, of the CAZAC sequence shall have a complex value representing the inphase and quadrature components of a QPSK-type sequence, as shown in Table 1.

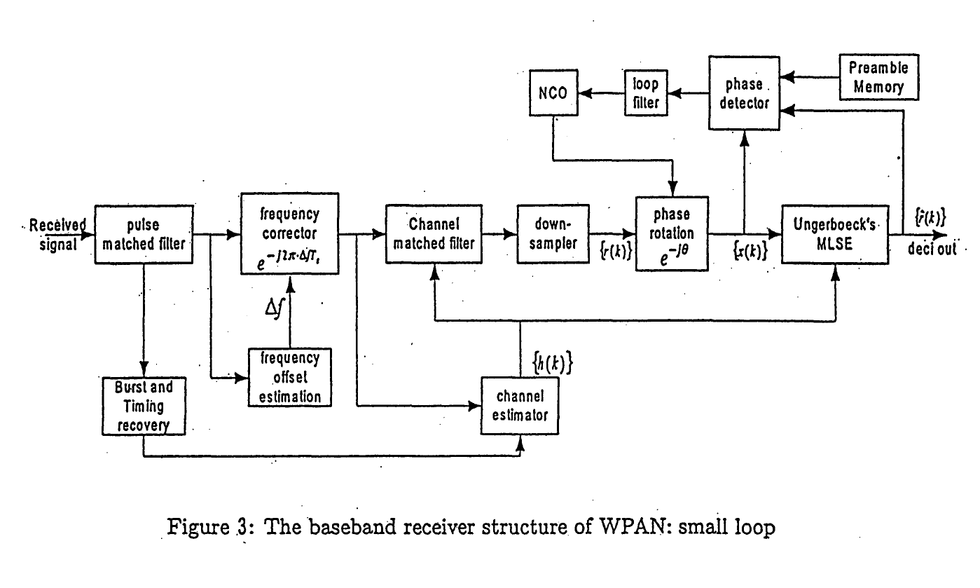

FIG. 3 is a block diagram of a baseband receiver which is employed to recover the modulated data. The received digitised samples are the complex signal sequence oversampled 4 times. Thereafter, the digitised complex samples are applied to the burst synchronisation and timing recovery circuit. In this circuit as well known in the art, a complex correlation is performed between the received samples and a complex replica of the preamble sequence stored in memory device. This correlation is to be computed upon the reception of each burst signal and will be used to provide both synchronisation and an estimate of the CIR. According to the preferred embodiment, the burst synchronisation and timing are accomplished by searching the complex correlation for the peak magnitude. Upon location of the synchronisation signal pattern, a CIR estimate are performed in accordance with well known channel sounding procedures. It will be appreciated by those skilled in the art that the correlation yields a complex result carrying both amplitude and phase information and represents a sounding of channel.

Based on the estimated timing and burst synchronisation, the preamble sequence is downsampled to symbol rate and input to the frequency offset circuit. With obtained frequency offset estimate, the phase of the received signal is rotated to correct any large frequency error. At the same time, the received signal samples are downsampled from the 4× symbol rate to 2× symbol rate and input to the matched filter.

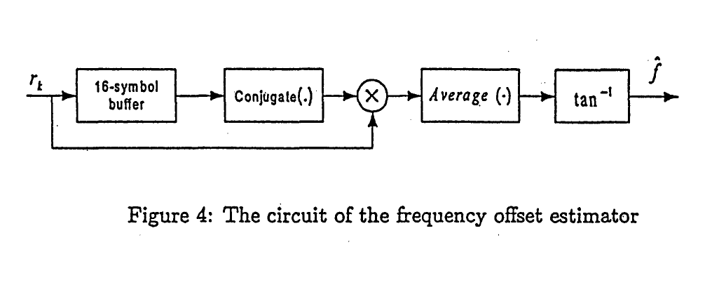

Preferably the frequency offset estimation and correction is achieved by the method described in applicant's co-pending application SG 200203670.5, the contents of which are hereby incorporated. A schematic of this estimator is shown in FIG. 4.

The frequency offset is coarsely estimated by modifying Cox's method proposed for OFDM system T. M. Schmidl and D. C. Cox, “Robust frequency and timing synchronization for OF DM”, IEEE Trans. Commun., Vol. 45, No.12, pp1613-1621, December 1997. This uses one unique symbol which has a repetition within half a symbol period to obtain the burst synchronisation and frequency offset estimation. This method allows a large acquisition range for the carrier frequency offset. In the present embodiment, utilising the unique property of CAZAC sequence, a modified method is used. Compared to the original method, this method requires a fixed length (16) correlator to derive the frequency offset.

A complex signal symbol aₖ, belonging to an M-ary alphabet, is transmitted over a complex linear channel characterized by impulse response h(t) (this filter represents the cascade of the transmitter filter, the physical channel, and the receiver filter). The complex envelope of the received signal can be expressed by a discrete model,

$${r}_{k} = {ⅇ}^{j ( 2 π Δ f k + φ )} {\sum }_{n = 0}^{L} {h}_{n} {a}_{k - n} + {n}_{k} \qquad ( 1 )$$

where nₖ denotes the equivalent baseband white Gaussian noise with power spectrum Nₒ/2, independent of the data sequence. {h(n)} is the CIR which is obtained by channel estimator, and A f denotes the frequency offset normalised to the symbol rate. The frequency offset estimator exploits the property of the periodic CAZAC sequence, and a correlation is performed according to the symbol rate,

$$\frac{1}{32} {\sum }_{k = 0}^{15} {r}_{k} {r}_{k - 16}^{*} = {ⅇ}^{j2π Δ f \cdot 16} \frac{1}{32} {\sum }_{k = 0}^{15} {\sum }_{n1} {\sum }_{n2} {h}_{n1} {h}_{n2}^{*} {c}_{k - n1} {c}_{k - 16 - n2}^{*} \qquad ( 2 )$$

In the following, two properties of the CAZAC sequence will be used. First, the preamble sequence made up of the repetition of 16 CAZAC symbols, i.e. cₖ=cₖ−16. Secondly, CAZAC sequence is a special PN sequence which has a good cyclic correlation property, i.e.;

$$\frac{1}{32} {\sum }_{k = 0}^{15} {c}_{k - n1} {c}_{k - 16 - n2}^{*} = \{ \begin{matrix}0 & n1 \neq n2 \\ 1 & n1 = n2\end{matrix} \qquad ( 3 )$$

Moreover, with a normalised Rayleigh fading channel, in most cases we have Σₙ₁|hₙ₁|²=1 (no complex power normalisation is needed) and hence the following relation is obtained,

$$\frac{1}{32} {\sum }_{k = 0}^{15} {r}_{k} {r}_{k - 16}^{*} = {ⅇ}^{j2π Δ f \cdot 16} \qquad ( 4 )$$

The estimated frequency offset can be represented as,

$$Δ \hat{f} = \frac{arg \{ \frac{1}{32} {\sum }_{k = 0}^{15} {r}_{k} {r}_{k - 16}^{*} \}}{2 π \times 16} \qquad ( 5 )$$

In Cox method, consider two repeated training symbols which are identical to each other at the receiver except for a phase shift caused by the carrier frequency offset. If the conjugate of the first symbol is multiplied by the second (delay time T_{d} later), the frequency offset can be estimated by some operations. The estimated range depends on delay time T_{d}. The effect of channel fading should be cancelled, therefore, the normalizer is needed.

In the modified method according to the present embodiment, the property of CAZAC sequence is used, and delay time is fixed at the length of each sequence (16) (the estimated normalised frequency offset is up to 0.06). The effect of channel fading is cancelled successfully just by a moving average, which decreases the implementation complexity. This is explained in more detail in the above referred co-pending application.

In accordance with the second embodiment, an MLSE equaliser is utilised in conjunction with the estimated CIR to recover the data sequence. There are two classic MLSE equaliser, Formey's MLSE receiver and Ungerboeck's unwhitened MLSE—see previous references. Ungerboeck's MLSE consists of a matched filter which maximises the SNR of the Viterbi input, a sampler operating at the symbol rate, and a modified Viterbi processor (which needn't square operation in metric calculation) for estimating the information sequence from the sampler output. In Formey's MLSE, the receiver consists of a whitened matched filter, i.e., a matched filter followed by a transversal filter that whitens the noise, a symbol rate sampler, and a conventional Viterbi processor to perform ML sequence estimation. In Formey's receiver, whitening of the noise is essential because the conventional Viterbi processor requires that noise components of successive samples be statistically independent.

Although Ungerboeck's MLSE has a lower complexity, Formey's MLSE is more extensively employed. This is because the two MLSEs have no essential difference in the implementation for TDMA systems where adaptive equaliser is required, and the matched filter and whitening matched filter have same complexity when implemented by LMS (least-means-square) or RLS (recursive-least-square) algorithm. Hence Ungerboeck's MLSE has only slight complexity advantage. Furthermore, Formey's MLSE is more attractive in the application since it adopts conventional Viterbi algorithm. However, this is not true for the indoor WAPN systems.

In an indoor wireless burst communication system over a quasi time-invarying fading channel, the preamble sequence is utilised to obtain quite accurate CIR estimate for each burst, which is constant for the whole burst. Hence the coefficients of the matched filter can be easily set up as h_{MF}=h*(−t). Whereas, the whitening filter converts the original overall CIR to a minimum-phase impulse response whose energy is concentrated in its first several samples. In the considered system, the whitening filter design possesses much higher complexity. First, the transmitted data is organised in bursts, each one containing a preamble sequence for timing, frequency offset and channel estimation. In most cases the preamble sequence is too short for the application of recursive adaptation algorithms like LMS or RLS algorithms for adjustment of the whitening filter coefficients. Therefore, a closed-form calculation using the result of channel estimation is necessary. Many methods well known in art either require matrix inversion or the solving of Yule-Walker equation, which introduce high complexity into Formey's receiver. Therefore Ungerboeck's MLSE, which does not need a whitening filter, substantially reduces the implementation complexity.

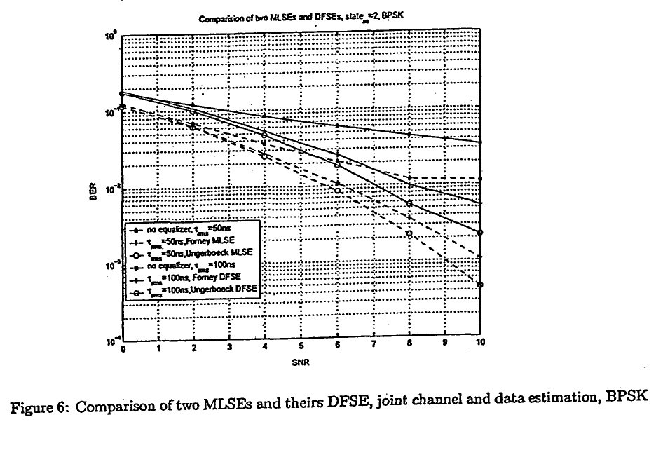

In Formey and Ungerboeck's MLSE, it will be appreciated by those skilled in the art that the matched filter (MF) provides the absolutely largest SNR, the elimination of ISI by a subsequent whitening filter diminishes the SNR. Therefore, Ungerboeck's MLSE is identical to the Formey's MLSE if there is no ISI at the MF output. In the presence of ISI, ISI at the MF output has not essential influence on the error performance of the Ungerboeck's MLSE, whereas ISI affects the error performance of the Formey's MLSE through the loss of SNR. Moreover, through simulations it has been demonstrated that Ungerboeck's MLSE and its reduced-complexity format (DFSE: decision feedback sequence estimate) can achieve better BER performance than Formey's MLSE and DFSE, which is shown in FIG. 6. Actually, this can be easily understood, the whitening filter is of infinite length in general, but an FIR implementation is generally required in practice, which makes the assumption of a minimum phase response at the whitening filter output not true in general. Consequently, the imperfection of the whitening filter design causes Formey's MLSE and DFSE performance degradation.

As previously discussed, embodiments of the present invention are directed at presenting a MLSE type receiver structure that integrates various estimation algorithms in an optimum way and adaptive manner for high-rate indoor wireless communications. Therefore, it is preferred to use Ungerboeck's MLSE receiver, which can optimise the system implementation and the BER performance. We will see that the optimality of adopting Ungerboeck's MLSE will be further demonstrated in the third embodiment. In accordance with the second embodiment, in operation, T/2-spaced matched filter is adopted in Ungerboeck's MLSE equaliser, hence each symbol is made up of 2 samples in the output of the matched filter. However, one sample per data symbol is sufficient to provide data/phase detection (which result in the minimised complexity for Viterbi processor). It is therefore desirable to pick the best sample per symbol according to the preferred synchronisation circuit.

The frequency error of the received signal is coarsely corrected with the estimated frequency offset, however, the residual frequency error and phase error still exist. After the frequency corrector, the Ungerboeck's MLSE is employed for data estimation. At the same time, estimated data output by MLSE equaliser is feedback to a phase lock loop (PLL) to compensate for the residual frequency error and phase jitter. Therefore, in accordance with the third embodiment, a novel integration of Ungerboeck's MLSE and PLL is proposed. After the frequency correction, the received signal can approximately be represented as:

$${r}_{k} = {ⅇ}^{j {φ}_{k}} {\sum }_{n = 0}^{L} {h}_{n} {a}_{k - n} + {n}_{k} \qquad ( 6 )$$

where Øₖ represents the phase error due to residual frequency error and phase noise. In this embodiment, a dual-mode phase-lock loop is utilised to remove the residual frequency error and phase noise. In accordance with this embodiment, the preamble sequence is skillfully utilised, the Ungerboeck's MLSE equaliser and phase error detector are optimally integrated. The loop delay of PLL is minimised by trading off the implementation complexity and the acquisition speed and tracking performance of the PLL.

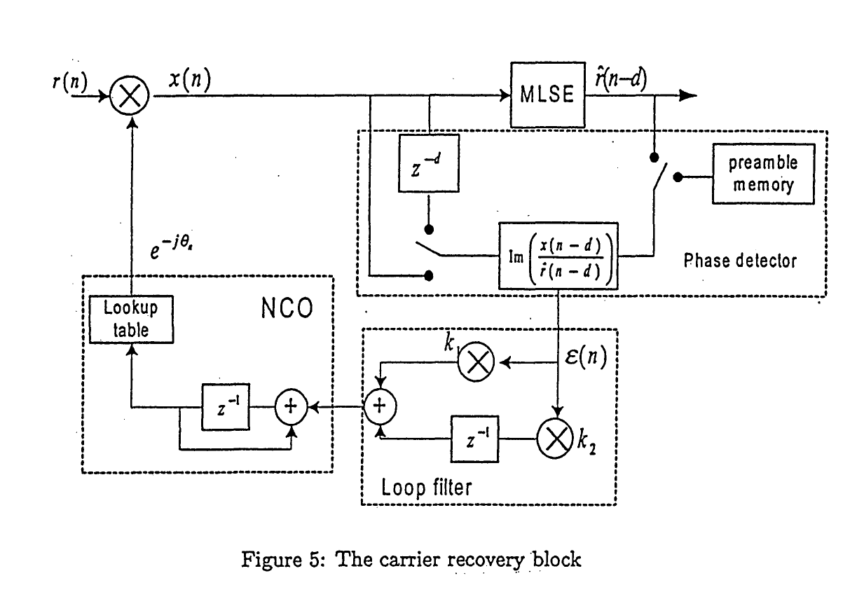

The carrier recovery circuit with data-aided and decision-directed mode PLL is shown in FIG. 5. The output of the phase rotator at the kth epoch, x(k) is expressed as

x(k)=rₖe^{-jθ(k)} (7)

where θ(k) is the carrier phase from the numerical control oscillator (NCO) for the phase rotation of the received signal. The detected phase error, which includes the effects of phase jitter, frequency offset and phase offset, can be expressed as,

$$ε ( k ) = Im [ \frac{x ( k )}{{c}_{k}} ] \qquad ( 8 )$$

Where ε can be approximated as the residual phase error because of the following conditions. First Ungerboeck's MLSE is adopted, in which the matched filter accomplishes the phase equalisation (i.e. s₀ is a real value, where {sᵢ, i=−L, . . . , L} denotes autocorrelation of the CIR); secondly the main path power is much higher than the interference path power

$$( \vert {s}_{0} \vert > {\sum }_{i = 1}^{L} \vert {s}_{i} \vert ,$$

which can be met in most cases.

In conventional schemes, the preamble data or decision output passes through a signal reconstruction module, and then is used to detect the phase error. The phase error detector of the embodiment results in less accurate detection; however this loss is trivial compared with the advantages generated.

In conventional schemes, the signal reconstruction require both the precursor and postcursor signal, and extra delay of two times of channel memory is introduced. Moreover, in the decision-directed mode, postcursor decision outputs are not available. In addition, the more precursor and postcurcor decision output are used, the larger high probability of error propagation. Therefore, using the proposed scheme, the loop delay is minimized and fast acquisition speed can be obtained by PLL. Moreover, this phase error detector possesses much smaller complexity, the loop delay is minimised, and fast acquisition speed can be obtained by PLL.

In the data-aided PLL utilising the known preamble sequence as the feedback, which result in zero loop delay except the delay introduced by the loop filter, the initialisation of the PLL can be efficiently accomplished, and the phase error can be quickly acquired. The PLL enters into lock state from pull-in state in a short time. Actually, this is a very efficient PLL training stage. After the preamble sequence is received and data segment is coming, the PLL is switched to the decision-directed mode. In the data segment, the corresponding phase detection function can be expressed as

$$ε ( k ) \approx I m [ \frac{x ( k - d )}{\hat{r} ( k - d )} ] = ε ( k - d ) \qquad ( 9 )$$

where r(k−d) denotes the recovered data output by the MLSE equaliser, and d denotes the decision delay in the MLSE equaliser. In this decision directed mode, the PLL tracks the variation of the phase error and compensates for it. The tracking range depends on the loop delay d, and the larger d results in the narrower tracking range. Therefore, the decision delay in the MLSE equaliser limits the carrier tracking performance.

After the phase detection, the detected error signal passes through the loop filter and derives the required phase to drive the NCO. These two function blocks can be expressed as:

θ(k)=θ(k−1)+{ε(k)}* {f(k)} (10)

where * represents convolutional operation and f(k) denotes the loop filter response. The setup of the loop filter f(k) is most crucial to the performance of the PLL. A second order PLL is adopted in this embodiment, and the transfer function of its digital loop can be represented as:

$$F ( z ) = {K}_{1} + \frac{{K}_{2}}{1 - {z}^{- 1}} \qquad ( 11 )$$

The loop filter coefficients K₁, K₂ can be calculated according to the tracking performance of PLL and noise bandwidth. The method to set K₁ and K₂ is well known in the art, and does not require additional discussion here.

If the PLL can efficiently compensate for the phase error caused by residual frequency error, phase offset and phase jitter, the input to the MLSE can be expressed as

$${x}_{k} = {r}_{k} {ⅇ}^{- j {θ}_{k}} = {\sum }_{n = - L}^{L} {s}_{n} {a}_{k - n} + {n}_{k} \qquad ( 12 )$$

evidently the input signal to MLSE equaliser is only the ISI—corrupted signal. Using Unger-broeck's MLSE, the desired data aₖ can be estimated.

It is well known in the art that the decision delay introduced by MLSE equaliser will significantly narrow the tracking range of the PLL, therefore an alternative to PSP-technique based carrier recovery is proposed. The present embodiment can achieve the same or slightly better performance than standard PSP technique when the same frequency corrector is used. Moreover, only 1/N implementation complexity and cost is needed, here N denotes the state number of Viterbi processor.

In standard PSP, the PLL is included into the MLSE algorithm itself. Therefore, for each state of Viterbi algorithm, one PLL is needed. However, in the embodiment, the phase is rotated outside of MLSE, and the decision output of MLSE is used for phase error detector (therefore only one detector), therefore, only one PLL is needed.

It is well known in the art that Ungerboeck's MLSE operates directly on the discrete output of the matched filter, and the modified Viterbi algorithm (VA) is adopted. The state of VA is

μₖ₋₁=(a_{k-L},a_{k-L+1}, . . . ,aₖ₋₁) (13)

the maximum likelihood (ML) estimation is obtained by maximising the metric given by

Γₖ(μₖ)=Γₖ₋₁(μₖ₋₁)+λ(μₖ₋₁,μₖ) (14)

where μ(μₖ₋₁, μₖ) is called branch metric. When PSP technique is used to recover the carrier, associated with the state transition μₖ→μₖ₊₁ the branch metrics become

$$λ ( {μ}_{k} \to {μ}_{k} + 1 ) = Re [ {\hat{a}}_{k} ( 2 {r}_{k} {ⅇ}^{- j {θ}_{k}} - {s}_{0} {a}_{k} - 2 {\sum }_{m = 1}^{L} {s}_{m} {a}_{k - m} ) ] \qquad ( 15 )$$

where rₖ denotes the received signal after frequency corrector, and âₖ denotes the decision of aₖ. θ is the estimated phase error, which is derived by the PSP method and adapted by the LMS algorithm. Using PSP technique, âₖ can be obtained, and the desired phase error is

\hat{θ}ₖ₊₁=\hat{θ}ₖ+K₁Im{rₖâₖe^{-j\hat{θ}}^{ₖ}} (16)

where K₁ is a constant. Comparing (16) with (10), we can see that LMS method is equivalent to the first order PLL method, except that the second component in (16) is the phase error Im{rₖ*âₖe^{-jθk}} is the loop filter of the first-order PLL.

The above discussion on the PSP-based MLSE receiver indicates that a PLL is needed for each state of Viterbi processor. Moreover, besides the survivor metrics for each state, the phase metric for each state are required to be stored. Hence the required storage is also doubled. Whereas only one PLL is needed in the present invention. If there are N states for Viterbi processor, the complexity of the present invention is only 1/N of the PSP based MLSE receiver.

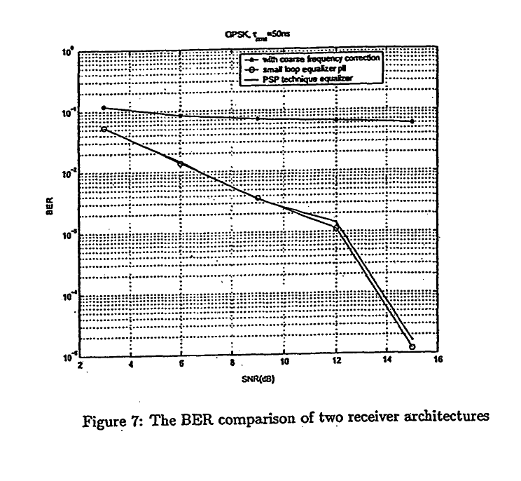

As is known a first order PLL can only track the phase step variation, and the second order PLL has much faster and wide tracking performance than the first order PLL especially in the presence of residual frequency error. Using the same system architecture, the BER comparison of PSP receiver and the present invention is shown in FIG. 7, which clearly indicates that the present invention can achieve equivalent or slightly better performance than PSP receiver. The embodiments of the present invention are optimally combined by trading off the tracking range, complexity and performance.

The invention is applicable to the receiver of high-rate wireless indoor communications, especially in wireless indoors communications systems which employ time-division burst transmission, where the rate of change of CIR is slower than the burst duration.

TABLE 1
CAZAC sequence

| CAZAC sequence element | Value |
|---|---|
| c₀ | 1 + j |
| c₁ | 1 + j |
| c₂ | 1 + j |
| c₃ | 1 + j |
| c₄ | −1 + j |
| c₅ | −1 − j |
| c₆ | 1 − j |
| c₇ | 1 + j |
| c₈ | −1 − j |
| c₉ | 1 + j |
| c₁₀ | −1 − j |
| c₁₁ | 1 + j |
| c₁₂ | 1 − j |
| c₁₃ | −1 − j |
| c₁₄ | −1 + j |
| c₁₅ | 1 + j |

1. A phase lock loop (PLL) circuit for receiving a burst signal including a repeated preamble sequence and a data sequence; the circuit comprising:
a maximum likelihood sequence estimator (MLSE) and means for determining the phase difference between a signal at the output of the MLSE and a corresponding delayed signal at the input of the MLSE;
phase rotating means for rotating the phase of said burst signal dependent on said phase difference, the output of said means being coupled to the MLSE input;
wherein the phase determining means is further arranged to determine the phase difference between a non-delayed signal at the MLSE input and a stored preamble sequence signal.

2. A circuit according to claim 1 wherein the phase determining means is arranged to determine the phase difference between said preamble memory and said non-delayed MLSE input when said signal is carrying said preamble sequence; and wherein said phase determining means is arranged to determine the phase difference between said MLSE output and said delayed MLSE input when said signal is carrying said data sequence.

3. A circuit according to claim 1 wherein said MLSE is an Ungerbroeck's type MLSE.

4. A circuit according to claim 1 wherein the phase determining means comprises a phase detector and a switching means;
the phase detector having a first input switchably coupled to the MLSE input and a delay means coupled to the MLSE input, the delay means for delaying the MLSE input signal by a delay time corresponding to the processing delay of the MLSE; and a second input switchably coupled to the MLSE output and a preamble memory means which stores said preamble sequence signal;
processing means arranged to determine the phase difference between the first and second inputs, the processing means arranged to determine the imaginary part of dividing the second input by the first input; said part corresponding to the phase difference.

5. A circuit according to claim 1 wherein the phase rotating means comprises a mixer; and a second order filter and a NCO are coupled between the phase detector output and said mixer.

6. A receiver for receiving a burst signal including a repeated preamble sequence and a data sequence; the receiver comprising a PLL circuit according to claim 1.

7. A receiver according to claim 6 further comprising a preamble frequency offset estimator having:
means for differentially multiplying a sample of a first said preamble sequence with a corresponding sample of a second said preamble sequence;
means for determining a phase rotation angle dependent on said difference and which angle is indicative of said estimate.

8. A receiver according to claim 7 further comprising a frequency shifter which shifts the phase of said received signal by said phase rotation angle.

9. A carrier recovery architecture for receiving a burst signal including a repeated training sequence and a data sequence; the architecture comprising:
a PLL having a mixer which receives a signal, an MLSE having an input coupled to the mixer, and a phase detector, the phase detector arranged to determine the phase difference between a signal at an output of the MLSE and a corresponding delayed signal at the MLSE input;
the PLL further having mixer input means which is arranged to provide a rotating signal to the mixer in order to adjust the frequency of the received signal which the mixer outputs to the MLSE, said rotating signal being dependent on said phase difference;
wherein the phase detector is arranged to be switch-able between said MLSE output and a training sequence memory, and between said MLSE delayed input and a non-delayed MLSE input.

10. A phase detector having an input coupled to the output of a maximum likelihood sequence estimator (MLSE) and a second input coupled to the input of said MLSE; the detector comprising:
delay means for delaying the second input signal by a delay time corresponding to the processing delay of the MLSE;
processing means arranged to determine the phase difference between the first and delayed second inputs;
the processing means arranged to determine the imaginary part of the result of dividing the second input by the first input; said part corresponding to the phase difference.

11. A detector according to claim 9 further comprising switching means arranged to switch said second input to said MLSE input (non-delayed) and to switch said first input to a sequence memory means.
